(19) United States
(12) Patent Application Publication
(10) Pub. No.: US 2026/0123072 A1
(43) Pub. Date: Apr. 30, 2026

(54) SENSOR PACKAGE STRUCTURE WITH NO AIR CAVITY THEREIN AND MANUFACTURING METHOD THEREOF

(71) Applicant: TONG HSING ELECTRONIC INDUSTRIES, LTD., Taoyuan City (TW)

(72) Inventors: CHIH-YANG HSU, Taoyuan City (TW); I-LING KO, Taoyuan City (TW); KE-YU WAN, Taoyuan City (TW); CHIA-MIN WU, Taoyuan City (TW); Kuan-Hsun Wu, Taoyuan City (TW)

(21) Appl. No.: 18/983,367

(22) Filed: Dec. 17, 2024

(30) Foreign Application Priority Data
Oct. 29, 2024 (TW) 113141164

(51) Int. Cl. H10F 39/00; H01L 23/00; H01L 25/16; H10F 39/95

(52) U.S. Cl. CPC H10F 39/804; H10F 39/011; H10F 39/8053; H10F 39/95; H10W 90/00; H10F 39/811; H10W 72/351

(57) ABSTRACT

A sensor package structure with no air cavity therein and a manufacturing method thereof are provided. The sensor package structure includes a substrate, a sensing module disposed on the substrate, and an opaque encapsulant that is formed on the substrate. The sensing module includes a sensor chip mounted on the substrate, a first transparent adhesive layer adhered to the sensor chip, and a first glass that is adhered to the first transparent adhesive layer. The sensor chip is electrically coupled to the substrate, and the first transparent adhesive layer is stacked on a sensing region of the sensor chip. The sensing module is embedded in the opaque encapsulant, and an outer surface of the first glass is at least partially exposed from the opaque encapsulant.

### CROSS-REFERENCE TO RELATED PATENT APPLICATION

This application claims the benefit of priority to Taiwan Patent Application No. 113141164, filed on Oct. 29, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a sensor package structure, and more particularly to a sensor package structure with no air cavity therein and a manufacturing method thereof.

### BACKGROUND OF THE DISCLOSURE

A conventional optical package structure is manufactured by assembling a glass onto a housing and then packaging an optical component in the case. However, molds for the conventional optical package structures need to be prepared in different shapes and structures that correspond in shape to different housings, so that a size of the conventional optical package structure is difficult to be effectively reduced.

### SUMMARY OF THE DISCLOSURE

In response to the above-referenced technical inadequacies, the present disclosure provides a sensor package structure with no air cavity therein and a manufacturing method thereof for effectively improving on the issues associated with conventional optical package structures.

In order to solve the above-mentioned problems, one of the technical aspects adopted by the present disclosure is to provide a sensor package structure with no air cavity therein. The sensor package structure includes a substrate, a sensing module, a light-emitting module, and an opaque encapsulant. The substrate has an upper surface and a lower surface that is opposite to the upper surface. The sensing module is disposed on the substrate and includes a sensor chip, a first transparent adhesive layer, and a first glass. The sensor chip is mounted on the upper surface of the substrate and is electrically coupled to the substrate. Moreover, a top surface of the sensor chip has a sensing region. The first transparent adhesive layer is adhered to the top surface of the sensor chip and is stacked on the sensing region. The first glass is adhered to the first transparent adhesive layer and is configured to filter light of a first spectral band. The light-emitting module is disposed on the substrate and is spaced apart from the sensing module. The light-emitting module includes a light-emitting chip, a second transparent adhesive layer, and a second glass. The light-emitting chip is mounted on the upper surface of the substrate and is electrically coupled to the substrate. The second transparent adhesive layer is adhered to the light-emitting chip and is stacked on a light-emitting surface of the light-emitting chip. The second glass is adhered to the second transparent adhesive layer. Moreover, an outer surface of the second glass is coplanar with an outer surface of the first glass, and the second glass is configured to filter light of a second spectral band that is different from the first spectral band. The opaque encapsulant is formed on the upper surface of the substrate. The sensing module and the light-emitting module are embedded in the opaque encapsulant, and at least part of the outer surface of the first glass and at least part of the outer surface of the second glass are exposed from the opaque encapsulant.

In order to solve the above-mentioned problems, another one of the technical aspects adopted by the present disclosure is to provide a manufacturing method of a sensor package structure with no air cavity therein. The manufacturing method includes a chip-bonding step, an adhering step, and a packaging step. The chip-bonding step is implemented by mounting a sensor chip and a light-emitting chip onto an upper surface of a substrate. The sensor chip and the light-emitting chip are spaced apart from each other. The adhering step is implemented by adhering a first glass onto a sensing region of the sensor chip through a first transparent adhesive layer so as to be jointly defined as a sensing module and by adhering a second glass onto a light-emitting surface of the light-emitting chip through a second transparent adhesive layer so as to be jointly defined as a light-emitting module. An outer surface of the second glass is coplanar with an outer surface of the first glass, the first glass is configured to filter light of a first spectral band, and the second glass is configured to filter light of a second spectral band that is different from the first spectral band. The packaging step is implemented by forming an opaque encapsulant on the upper surface of the substrate. The sensing module and the light-emitting module are embedded in the opaque encapsulant, and at least part of the outer surface of the first glass and at least part of the outer surface of the second glass are exposed from the opaque encapsulant.

In order to solve the above-mentioned problems, yet another one of the technical aspects adopted by the present disclosure is to provide a manufacturing method of a sensor package structure with no air cavity therein. The manufacturing method includes a modularizing step, a chip-bonding step, and a packaging step. The modularizing step is implemented by respectively adhering a plurality of first glasses onto predetermined sensing regions of a first wafer through a plurality of first transparent adhesive layers, and then cutting the first wafer to form a plurality of sensor chips that are spaced apart from each other and that have the predetermined sensing regions, respectively. Each of the sensor chips, a corresponding one of the first transparent adhesive layers, and a corresponding one of the first glasses are jointly defined as one of a plurality of sensing modules. The chip-bonding step is implemented by mounting the sensor chip of one of the sensing modules and a light-emitting module onto an upper surface of a substrate. The light-emitting module includes a light-emitting chip mounted on the upper surface, a second transparent adhesive layer adhered to the light-emitting chip, and a second glass that is adhered to the second transparent adhesive layer. The first glass is configured to filter light of a first spectral band, and the second glass is configured to filter light of a second spectral band that is different from the first spectral band. The packaging step is implemented by forming an opaque encapsulant on the upper surface of the substrate. The sensing module and the light-emitting module are embedded in the opaque encapsulant, and at least part of an outer surface of the first glass and at least part of an outer surface of the second glass are exposed from the opaque encapsulant.

In order to solve the above-mentioned problems, further another one of the technical aspects adopted by the present disclosure is to provide a sensor package structure with no air cavity therein. The sensor package structure includes a substrate, a sensing module, and an opaque encapsulant. The substrate has an upper surface and a lower surface that is opposite to the upper surface. The sensing module is disposed on the substrate and includes a sensor chip, a first transparent adhesive layer, and a first glass. The sensor chip is mounted on the upper surface of the substrate and is electrically coupled to the substrate. Moreover, a top surface of the sensor chip has a sensing region. The first transparent adhesive layer is adhered to the top surface of the sensor chip and is stacked on the sensing region. The first glass is adhered to the first transparent adhesive layer and is configured to filter light of a first spectral band. The opaque encapsulant is formed on the upper surface of the substrate. The sensing module is embedded in the opaque encapsulant, and at least part of the outer surface of the first glass is exposed from the opaque encapsulant.

Therefore, the sensor chip and the light-emitting chip in the sensor package structure of the present disclosure are provided with the first transparent adhesive layer and the second transparent adhesive layer that are respectively stacked thereon for adhering the first glass and the second glass, such that the opaque encapsulant can be configured to replace a conventional housing, thereby effectively reducing a manufacturing cost and an overall size of the sensor package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure with no air cavity therein according to a first embodiment of the present disclosure;

FIG. 2 is a schematic cross-sectional view taken along line II-II of FIG. 1;

FIG. 3 is a schematic top view of FIG. 1;

FIG. 4 is a schematic cross-sectional view showing the sensor package structure in another configuration according to the first embodiment of the present disclosure;

FIG. 5 is a schematic top view of FIG. 4;

FIG. 6 is a schematic cross-sectional view showing the sensor package structure in yet another configuration according to the first embodiment of the present disclosure;

FIG. 7 is a schematic cross-sectional view showing the sensor package structure of FIG. 2 that is provided without any light-emitting module;

FIG. 8 is a schematic cross-sectional view showing the sensor package structure of FIG. 4 that is provided without any light-emitting module;

FIG. 9 is a schematic view showing a chip-bonding step of a manufacturing method of the sensor package structure according to the first embodiment of the present disclosure;

FIG. 10 and FIG. 11 are schematic views showing an adhering step of the manufacturing method of the sensor package structure according to the first embodiment of the present disclosure;

FIG. 12 and FIG. 13 are schematic views showing a preparing step of the manufacturing method of the sensor package structure according to a second embodiment of the present disclosure;

FIG. 14 is a schematic view showing the adhering step of the manufacturing method of the sensor package structure according to the second embodiment of the present disclosure;

FIG. 15 and FIG. 16 are schematic views showing a modularizing step of the manufacturing method of the sensor package structure according to a third embodiment of the present disclosure;

FIG. 17 is a schematic view showing the chip-bonding step of the manufacturing method of the sensor package structure according to the third embodiment of the present disclosure; and

FIG. 18 to FIG. 20 are schematic views showing the modularizing step of the manufacturing method of the sensor package structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

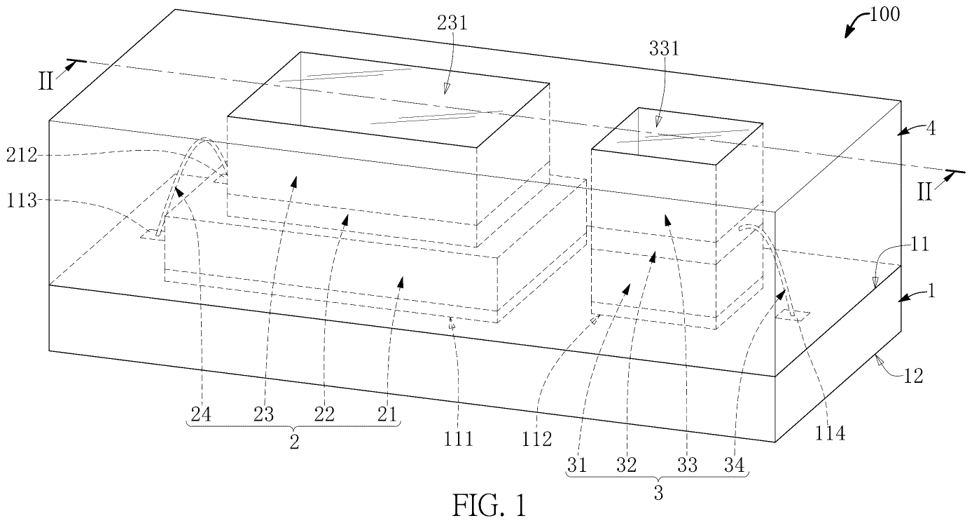

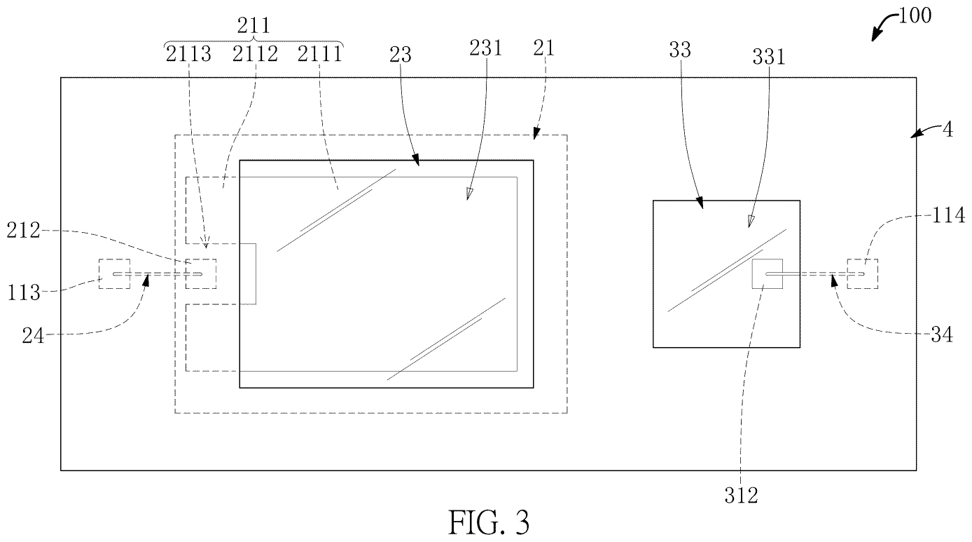

Referring to FIG. 1 to FIG. 11, a first embodiment of the present disclosure is provided. As shown in FIG. 1 to FIG. 3, the present embodiment provides a sensor package structure 100 with no air cavity therein, which includes a substrate 1, a sensing module 2 mounted on the substrate 1, a light-emitting module 3 mounted on the substrate 1 and arranged adjacent to the sensing module 1, and an opaque encapsulant 4 that is formed on the substrate 1.

It should be noted that an interior of the sensor package structure 100 in the present embodiment is limited to having no air cavity, so that any package structure having air cavity is different from the sensor package structure 100 provided by the present embodiment. The following description describes the configuration and connection relationship of each component of the sensor package structure 100.

The substrate 1 of the present embodiment has a square shape or a rectangular shape, but the present disclosure is not limited thereto. The substrate 1 has an upper surface 11 and a lower surface 12 that is opposite to the upper surface 11. The upper surface 11 of the substrate 1 includes a first chip-bonding region 111 and a second chip-bonding region 112 that is arranged adjacent to and spaced apart from the first chip-bonding region 111, and the substrate 1 includes at least one first bonding pad 113 and at least one second bonding pad 114 that are arranged on the upper surface 11 thereof.

The at least one first bonding pad 113 is arranged adjacent to the first chip-bonding region 111, the at least one second bonding pad 114 is arranged adjacent to the second chip-bonding region 112, and the at least one first bonding pad 113 and the at least one second bonding pad 114 are located at two opposite sides of the first chip-bonding region 111 and the second chip-bonding region 112 away from each other. In addition, a quantity of the at least one first bonding pad 113 and/or a quantity of the at least one second bonding pad 114 can be adjusted or changed according to practical requirements, and the present disclosure is not limited thereto.

The sensing module 2 in the present embodiment includes a sensor chip 21 mounted on the substrate 1, a first transparent adhesive layer 22 adhered to the top surface of the sensor chip 21, a first glass 23 adhered to the first transparent adhesive layer 22, and at least one first metal wire 24 that electrically couples to the substrate 1 and the sensor chip 21.

It should be noted that the sensor chip 21 is mounted on the upper surface 11 of the substrate 1 (e.g., the first chip-bonding region 111), and the sensor chip 21 in the present embodiment is electrically coupled to the substrate 1 through the at least one first metal wire 24, but the present disclosure is not limited thereto. For example, in other embodiments of the present disclosure not shown in the drawings, the sensor chip 21 is fixed onto and electrically coupled to the substrate 1 in a flip-chip manner according to practical requirements, such that the sensing module 2 can be provided without the at least one first metal wire 24.

Specifically, a top surface of the sensor chip 21 has a sensing region 211 and at least one first connection pad 212. The number and position of the at least one first connection pad 212 correspond to those of the at least one first bonding pad 113. In the present embodiment, two ends of the at least one first metal wire 24 are respectively connected to the at least one first bonding pad 113 and the at least one first connection pad 212, so that the substrate 1 can be electrically coupled to the sensor chip 21 through the at least one first metal wire 24. The at least one first metal wire 24 can be configured in a normal bonding manner or a reverse bonding manner according to design requirements, and the present disclosure is not limited thereto.

Specifically, the sensing region 211 has a main segment 2111 and two sub-segments 2112 that extend from the main segment 2111. In the present embodiment, an area of the main segment 2111 is substantially within a range from 80% to 95% of an area of the sensing region 211, the two sub-segments 2112 are respectively connected to two ends of one edge of the main segment 2111, and the at least one connection pad 212 is located in a region (e.g., a notch 2113) that is surrounded by the main segment 2111 and the two sub-segments 2112, but the present disclosure is not limited thereto.

The first transparent adhesive layer 22 is adhered to the top surface of the sensor chip 21 and is stacked on the sensing region 211, and the first glass 23 is adhered to the first transparent adhesive layer 22, such that the first transparent adhesive layer 22 is sandwiched (or connected) between the sensing region 211 of the sensor chip 21 and the first glass 23. In the present embodiment, outer lateral edges of the first glass 23 are preferably flush with outer lateral edges of the first transparent adhesive layer 22, the first glass 23 is a filtering sheet configured to filter light of a first spectral band (e.g., the first spectral band preferably covering light of a spectral band that can be sensed by the sensing region 211), but the present disclosure is not limited thereto. In addition, the first glass 23 can be a coated glass or an uncoated glass (e.g., a plain glass) according to practical requirements.

It should be noted that the structural relationship between the first glass 23 and the sensing region 211 can be adjusted or changed according to practical requirements. For example, in other embodiments of the present disclosure not shown in the drawings, the shape of the first glass 23 (or the first transparent adhesive layer 22) can correspond to (or can be identical to) the shape of the main segment 2111 of the sensing region 211. Specifically, a projection region defined by orthogonally projecting the first glass 23 onto the top surface of the sensor chip 21 overlaps an entirety of the main segment 2111 and does not overlap the two sub-segments 2112 and the at least one first connection pad 212. In other words, the first transparent adhesive layer 22 is adhered to and stacked on the entirety of the main segment 2111, but is not stacked on the two sub-segments 2112.

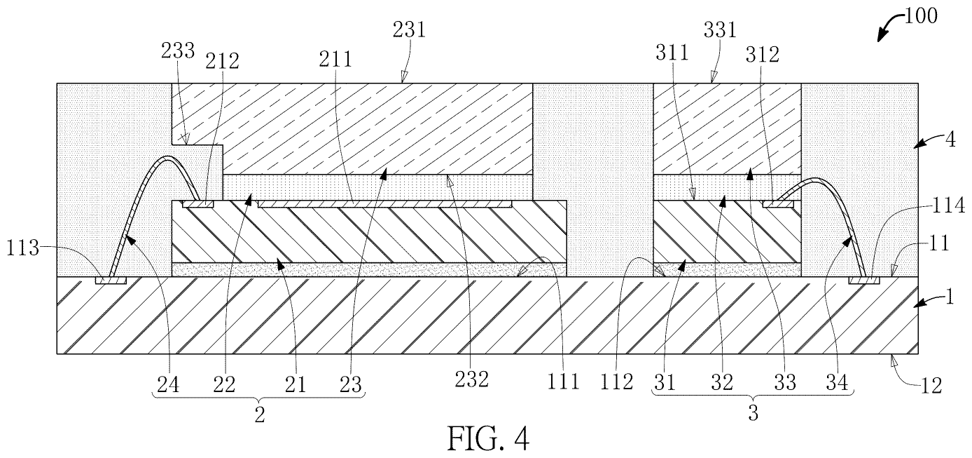

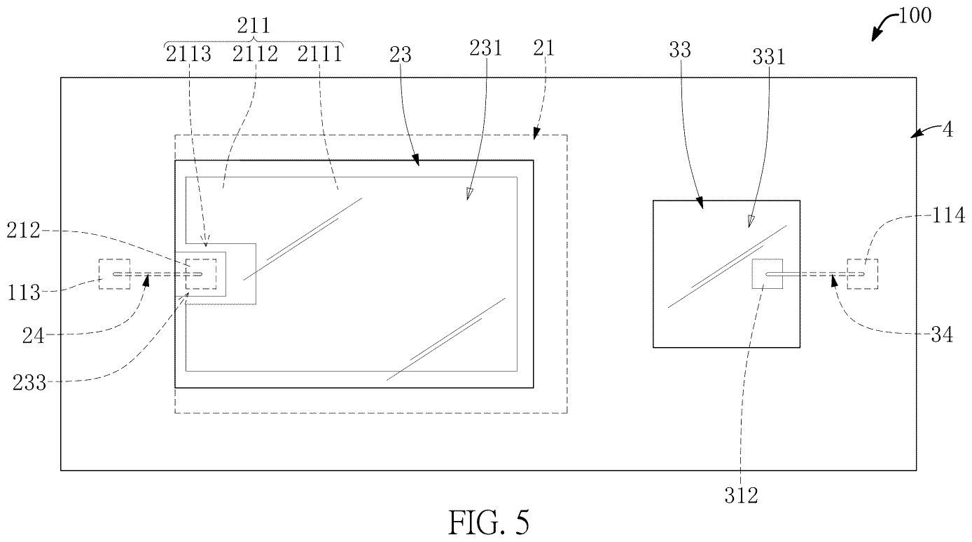

Or, as shown in FIG. 4 and FIG. 5, the first glass 23 has an outer surface 231, an inner surface 232 that is opposite to the outer surface 231 thereof, and an avoidance slot 233 that is recessed from the inner surface 232 thereof. Moreover, a part of the at least one first metal wire 24 is located in the avoidance slot 233. Furthermore, a projection region defined by orthogonally projecting the first glass 23 onto the top surface of the sensor chip 21 overlaps an entirety of the sensing region 211 (i.e., the main segment 2111 and the two sub-segments 2112) and the at least one first connection pad 212. In other words, the first transparent adhesive layer 22 is adhered to and stacked on the entirety of the sensing region 211 (i.e., the main segment 2111 and the two sub-segments 2112).

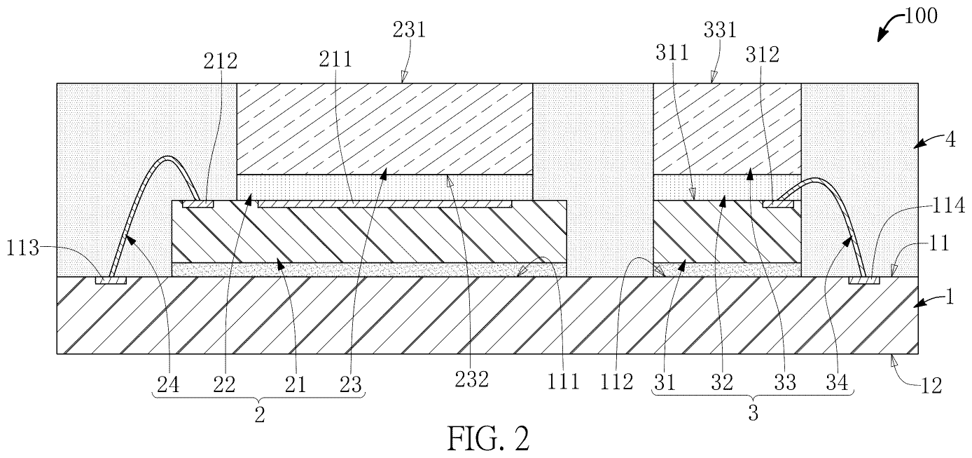

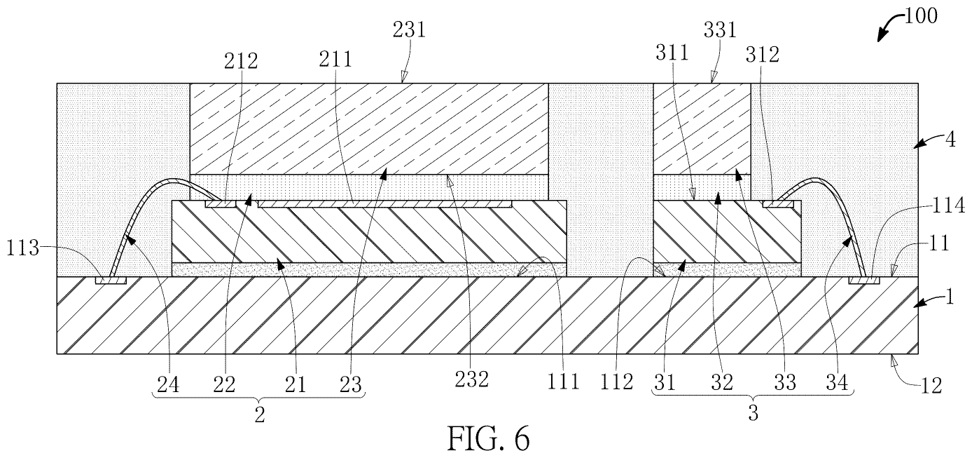

It should be noted that the structural relationship between the at least one first metal wire 24 and the first transparent adhesive layer 22 can be adjusted or changed according to practical requirements. For example, as shown in FIG. 6, the at least one first connection pad 212 and a part of the at least one first metal wire 24 are embedded in the first transparent adhesive layer 22; or, as shown in FIG. 2, the at least one first connection pad 212 and the at least one first metal wire 24 are not in contact with the first transparent adhesive layer 22.

As shown in FIG. 1 to FIG. 3, the light-emitting module 3 is arranged adjacent to and spaced apart from the sensing module 2. The light-emitting module 3 in the present embodiment includes a light-emitting chip 31 mounted on the substrate 1, a second transparent adhesive layer 32 adhered to the light-emitting chip 31, a second glass 33 adhered to the second transparent adhesive layer 32, and at least one second metal wire 34 that electrically couples the substrate 1 and the light-emitting chip 31.

It should be noted that the light-emitting chip 31 is mounted on the upper surface 11 of the substrate 1 (e.g., the second chip-bonding region 112), and the light-emitting chip 31 in the present embodiment is electrically coupled to the substrate 1 through the at least one second metal wire 34, but the present disclosure is not limited thereto. For example, in other embodiments of the present disclosure not shown in the drawings, the light-emitting chip 31 is fixed onto and electrically coupled to the substrate 1 in a flip-chip manner according to practical requirements, such that the light-emitting module 3 can be provided without the at least one second metal wire 34.

Specifically, the light-emitting chip 31 in the present embodiment is a light-emitting diode (LED) chip, but the present disclosure is not limited thereto. The light-emitting chip 31 has a light-emitting surface 311 and at least one second connection pad 312 that is arranged adjacent to the light-emitting surface 311. The number and position of the at least one second connection pad 312 correspond to those of the at least one second bonding pad 112. In the present embodiment, two ends of the at least one second metal wire 34 are respectively connected to the at least one second bonding pad 114 and the at least one second connection pad 312, so that the substrate 1 can be electrically coupled to the light-emitting chip 31 through the at least one second metal wire 34. The at least one second metal wire 34 can be configured in a normal bonding manner or a reverse bonding manner according to design requirements, and the present disclosure is not limited thereto.

The second transparent adhesive layer 32 is adhered to a top side of the light-emitting chip 21 and is stacked on the light-emitting surface 311, and the second glass 33 is adhered to the second transparent adhesive layer 32, such that the second transparent adhesive layer 32 is sandwiched (or connected) between the light-emitting surface 311 of the light-emitting chip 31 and the second glass 33. In the present embodiment, outer lateral edges of the second glass 33 are preferably flush with outer lateral edges of the second transparent adhesive layer 32, the second glass 33 is a filtering sheet configured to filter light of a second spectral band that is different from the first spectral band, but the present disclosure is not limited thereto. In addition, the second glass 33 can be a coated glass or an uncoated glass (e.g., a plain glass) according to practical requirements.

It should be noted that the structural relationship between the at least one second metal wire 34 and the second transparent adhesive layer 32 can be adjusted or changed according to practical requirements. For example, as shown in FIG. 2, the at least one second connection pad 312 and a part of the at least one second metal wire 34 are embedded in the second transparent adhesive layer 32; or, as shown in FIG. 6, the at least one second connection pad 312 and the at least one second metal wire 34 are not in contact with the second transparent adhesive layer 32.

The opaque encapsulant 4 is formed on the upper surface 11 of the substrate 1, the sensing module 2 and the light-emitting module 3 are embedded in the opaque encapsulant 4, and at least part of the outer surface 231 of the first glass 23 and at least part of the outer surface 331 of the second glass 33 are exposed from the opaque encapsulant 4. In addition, as shown in FIG. 2 and FIG. 6, the at least one first metal wire 24 and/or the at least one second metal wire 34 can be partially or entirely embedded in the opaque encapsulant 4 according to practical requirements.

Moreover, the opaque encapsulant 4 in the present embodiment is a molding compound, but the present disclosure is not limited thereto. For example, in other embodiments of the present disclosure not shown in the drawings, the opaque encapsulant 4 can be a solidified liquid compound or can include a solidified liquid compound and a molding compound that is formed on a top side of the solidified liquid compound.

In summary, the sensor chip 21 and the light-emitting chip 31 in the sensor package structure 100 of the present embodiment are provided with the first transparent adhesive layer 22 and the second transparent adhesive layer 32 that are respectively stacked thereon for adhering the first glass 23 and the second glass 33, such that the opaque encapsulant 4 can be configured to replace a conventional housing, thereby effectively reducing a manufacturing cost and an overall size of the sensor package structure 100.

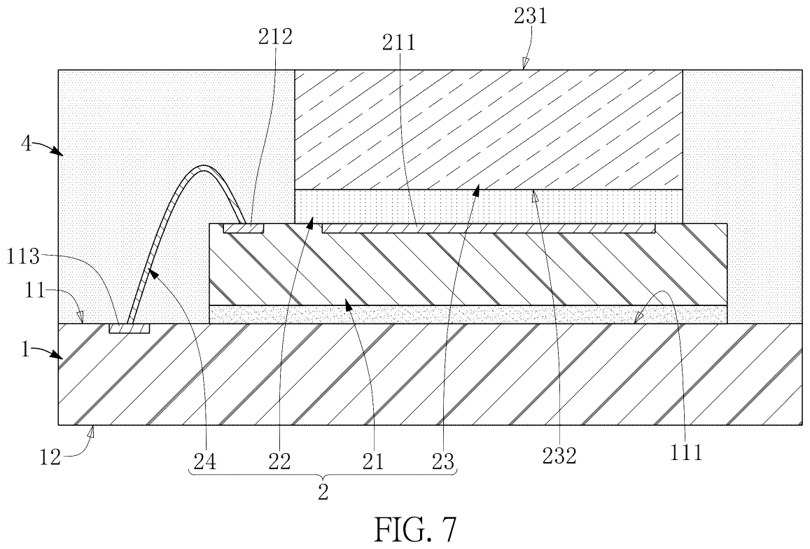

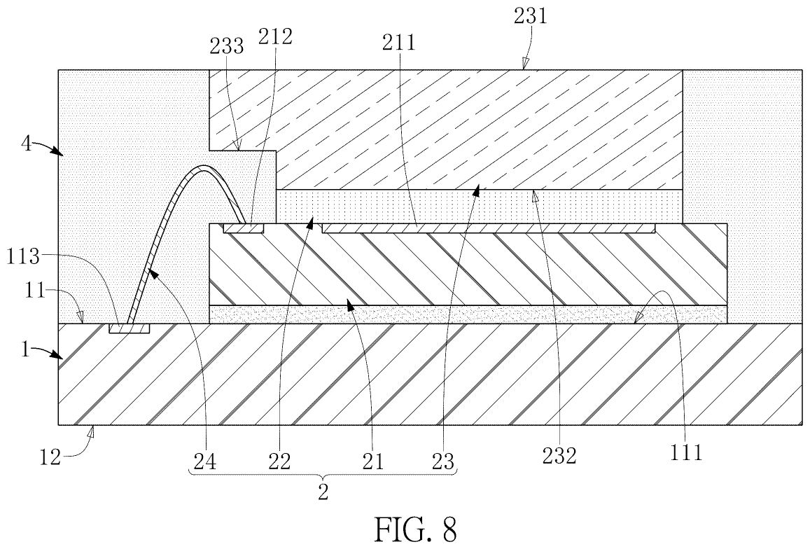

It should be noted that the second package structure 100 in the present embodiment includes the substrate 1, the sensing module 2, the light-emitting module 3, and the opaque encapsulant 4, but the present disclosure is not limited thereto. For example, as shown in FIG. 7 and FIG. 8, the second package structure 100 can be provided without the light-emitting module 3 according to practical requirements. In other words, the second package structure 100 can include the substrate 1, the sensing module 2, and the opaque encapsulant 4.

The present embodiment provides a manufacturing method of a sensor package structure with no air cavity therein for producing the sensor package structure 100 described in the above description, and the component described in the following steps of the manufacturing method can be referred to in the above description of the sensor package structure 100 for the sake of brevity, but the present disclosure is not limited thereto. For example, in other embodiments of the present disclosure not shown in the drawings, the sensor package structure 100 can be manufactured by implementing methods other than the manufacturing method of the present embodiment.

In the present embodiment, the manufacturing method (sequentially) includes a chip-bonding step, an adhering step, and a packaging step. The following description describes the steps of the manufacturing method in sequence.

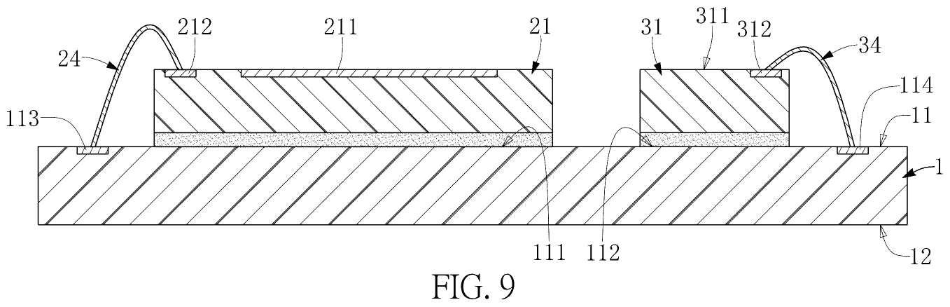

As shown in FIG. 9, the chip-bonding step is implemented by mounting a sensor chip 21 and a light-emitting chip 31 onto an upper surface 11 of a substrate 1, in which the sensor chip 21 and the light-emitting chip 31 are spaced apart from each other. In the present embodiment, the sensor chip 21 is electrically coupled to the substrate 1 through at least one first metal wire 24, and the light-emitting chip 31 is electrically coupled to the substrate 1 through at least one second metal wire 34.

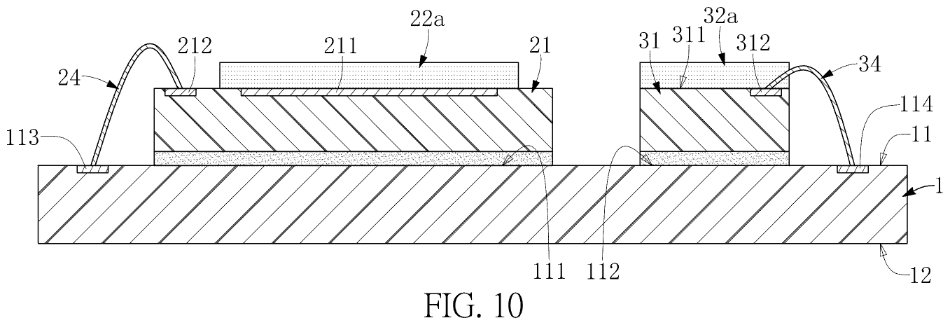

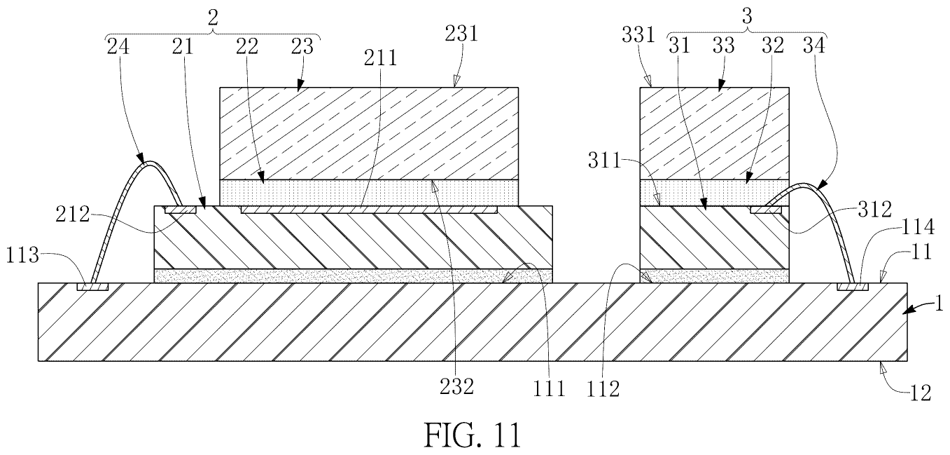

As shown in FIG. 10 and FIG. 11, the adhering step is implemented by adhering a first glass 23 onto a sensing region 211 of the sensor chip 21 through a first transparent adhesive layer 22 so as to be jointly defined as a sensing module 2, and by adhering a second glass 33 onto a light-emitting surface 311 of the light-emitting chip 31 through a second transparent adhesive layer 32 so as to be jointly defined as a light-emitting module 3, in which an outer surface 331 of the second glass 33 is coplanar with an outer surface 231 of the first glass 23. In the present embodiment, the first glass 23 is configured to filter light of a first spectral band, and the second glass 33 is configured to filter light of a second spectral band that is different from the first spectral band.

Specifically, in the adhering step of the present embodiment, a first optical colloid 22a and a second optical colloid 32a are respectively formed on the sensing region 211 of the sensor chip 21 and the light-emitting surface 331 of the light-emitting chip 31 in a dispensing manner and are in a semi-solidified state, the first glass 23 and the second glass 33 are respectively adhered to the first optical colloid 22a and the second optical colloid 32a, and the first optical colloid 22a and the second optical colloid 32a are solidified to respectively form the first transparent adhesive layer 22 and the second transparent adhesive layer 32.

As shown in FIG. 2, the packaging step is implemented by forming an opaque encapsulant 4 on the upper surface 11 of the substrate 1, in which the sensing module 2 and the light-emitting module 3 are embedded in the opaque encapsulant 4, and at least part of the outer surface 231 of the first glass 23 and at least part of the outer surface 331 of the second glass 33 are exposed from the opaque encapsulant 4.

### Second Embodiment

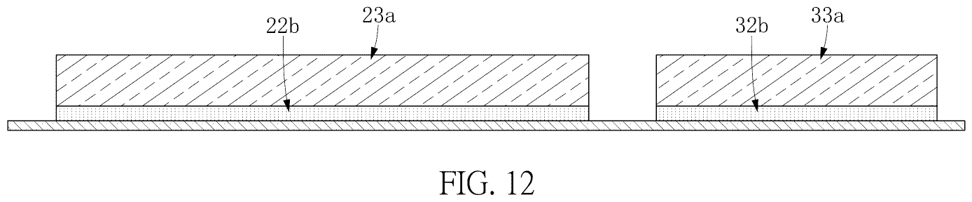

Referring to FIG. 12 to FIG. 14, a second embodiment of the present disclosure, which is similar to the first embodiment of the present disclosure, is provided. For the sake of brevity, descriptions of the same components or steps in the first and second embodiments of the present disclosure (e.g., the chip-bonding step and the packaging step) will be omitted herein, and the following description only discloses different features between the first and second embodiments.

In the present embodiment, the manufacturing method further includes a preparing step before implementing the adhering step, and the adhering step provided by the present embodiment is different from that of the first embodiment.

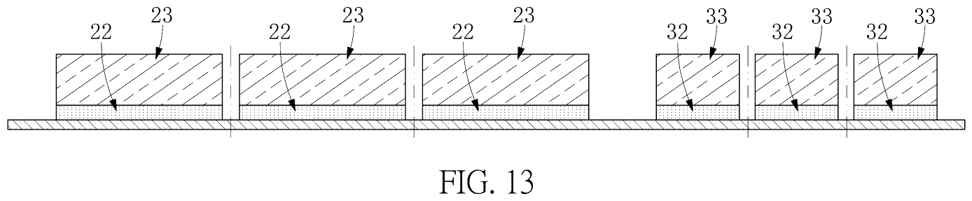

As shown in FIG. 12 and FIG. 13, the preparing step is implemented by adhering a first optical colloid tape 22b in solid mode to a first glass layer 23a and then cutting the first glass layer 23a and the first optical colloid tape 22b to form the first glasses 23 spaced apart from each other and the first transparent adhesive layers 22 that are respectively adhered to the first glasses 23. Moreover, in the preparing step, a second optical colloid tape 32b in solid mode to a second glass layer 33a and then cutting the second glass layer 33a and the second optical colloid tape 32b to form the second glasses 33 spaced apart from each other and the second transparent adhesive layers 32 that are respectively adhered to the second glasses 33.

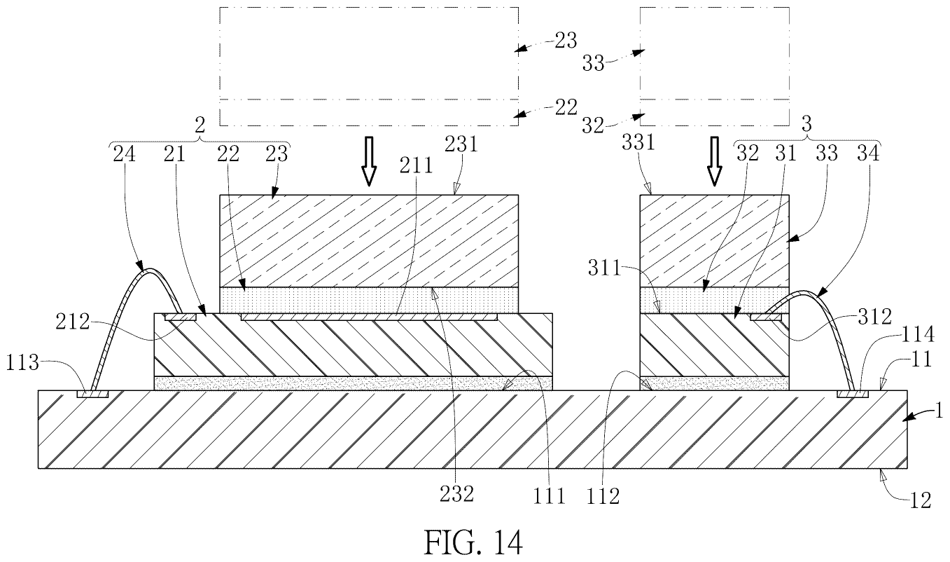

As shown in FIG. 14, in the adhering step of the present embodiment, one of the first glasses 23 is adhered to the sensing region 211 of the sensor chip 21 through a corresponding one of the first transparent adhesive layers 22 that is adhered thereto, thereby being jointly defined as the sensing module 2. Moreover, in the adhering step of the present embodiment, one of the second glasses 33 is adhered to the light-emitting surface 311 of the light-emitting chip 31 through a corresponding one of the second transparent adhesive layers 32 that is adhered thereto, thereby being jointly defined as the light-emitting module 3. In addition, the outer surface 331 of the one of the second glasses 33 is coplanar with the outer surface 231 of the one of the first glasses 23.

### Third Embodiment

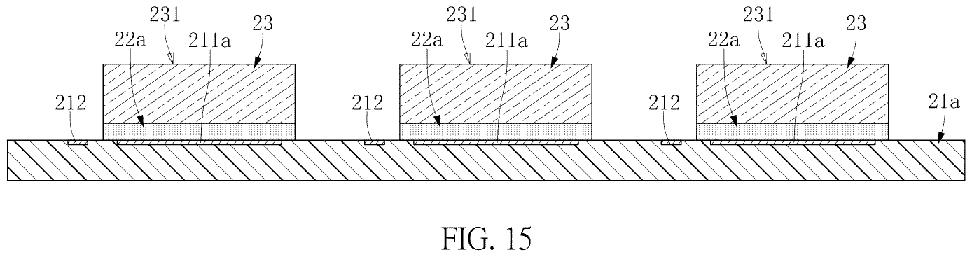

Referring to FIG. 15 to FIG. 17, a third embodiment of the present disclosure, which is similar to the first embodiment of the present disclosure, is provided. For the sake of brevity, descriptions of the same components or steps in the first and third embodiments of the present disclosure (e.g., the packaging step) will be omitted herein, and the following description only discloses different features between the first and third embodiments.

The present embodiment provides a manufacturing method of a sensor package structure with no air cavity therein for producing the sensor package structure 100 described in the first embodiment, and the component described in the following steps of the manufacturing method can be referred to in the above description of the sensor package structure 100 of the first embodiment for the sake of brevity, but the present disclosure is not limited thereto. For example, in other embodiments of the present disclosure not shown in the drawings, the sensor package structure 100 can be manufactured by implementing methods other than the manufacturing method of the present embodiment.

In the present embodiment, the manufacturing method (sequentially) includes a modularizing step, a chip-bonding step, and a packaging step. The following description describes the steps of the manufacturing method in sequence.

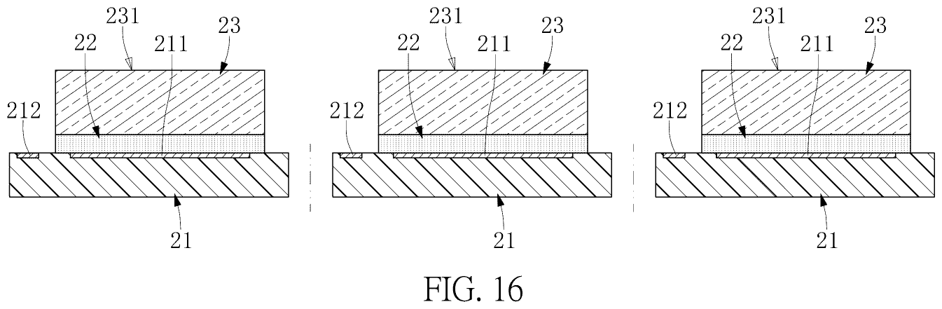

As shown in FIG. 15 and FIG. 16, the modularizing step is implemented by respectively adhering a plurality of first glasses 23 onto predetermined sensing regions 211a of a first wafer 21a through a plurality of first transparent adhesive layers 22, and then cutting the first wafer 21a to form a plurality of sensor chips 21 that are spaced apart from each other and that have the predetermined sensing regions 211a, respectively. Moreover, each of the sensor chips 21, a corresponding one of the first transparent adhesive layers 22, and a corresponding one of the first glasses 23 are jointly defined as one of a plurality of sensing modules 2.

Specifically, in the modularizing step of the present embodiment, a plurality of first optical colloids 22a are respectively formed on the predetermined sensing regions 211a of the first wafer 21a in a dispensing manner and are in a semi-solidified state (i.e., a B-stage mode) for being spaced apart from each other, the first glasses 23 are respectively adhered to the first optical colloids 22a, and then the first optical colloids 22a are solidified to respectively form the first transparent adhesive layers 22.

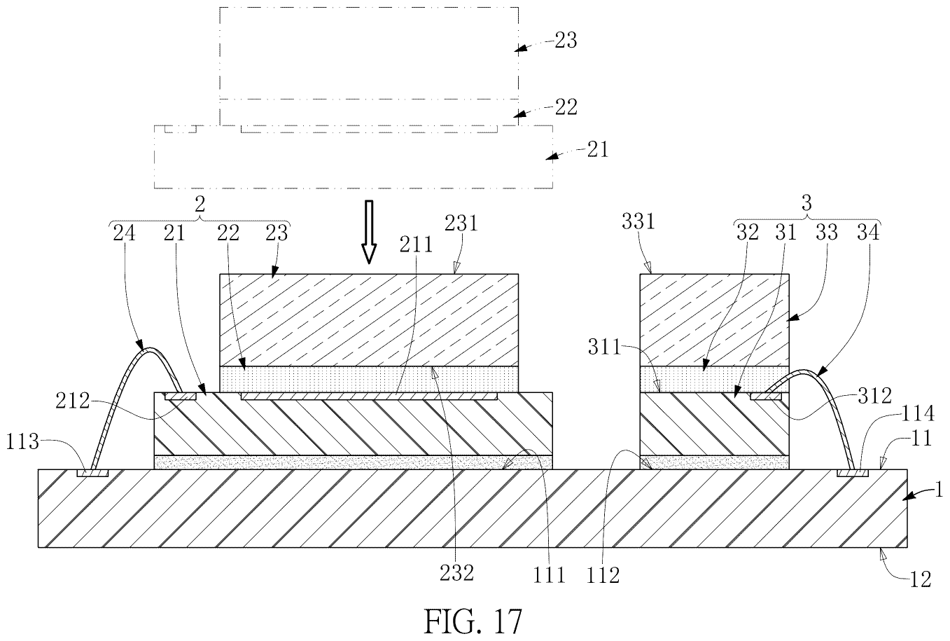

As shown in FIG. 17, the chip-bonding step is implemented by mounting the sensor chip 21 of one of the sensing modules 2 and a light-emitting module 3 onto an upper surface 11 of a substrate 1. The light-emitting module 3 includes a light-emitting chip 31 mounted on the upper surface 11, a second transparent adhesive layer 32 adhered to the light-emitting chip 31, and a second glass 33 that is adhered to the second transparent adhesive layer 32. Moreover, the first glass 23 is configured to filter light of a first spectral band, and the second glass 33 is configured to filter light of a second spectral band that is different from the first spectral band.

In the present embodiment, the sensor chip 21 is electrically coupled to the substrate 1 through at least one first metal wire 24, and the light-emitting chip 31 is electrically coupled to the substrate 1 through at least one second metal wire 34.

### Fourth Embodiment

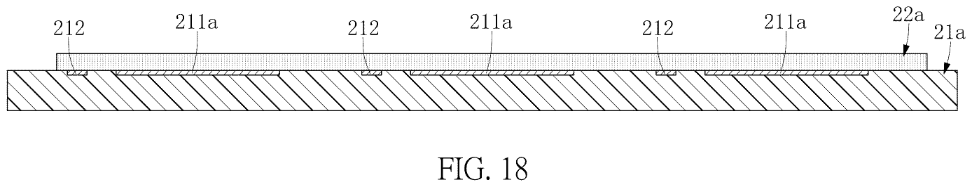

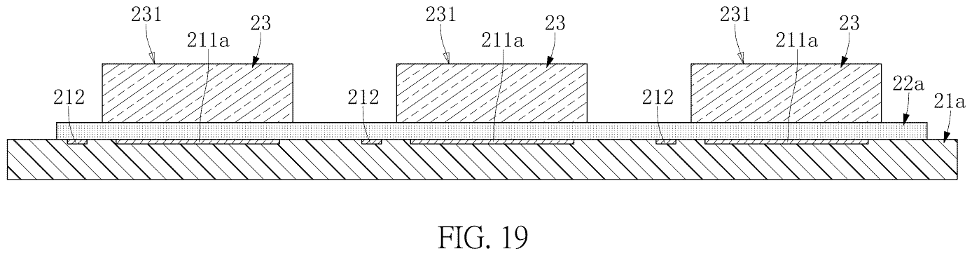

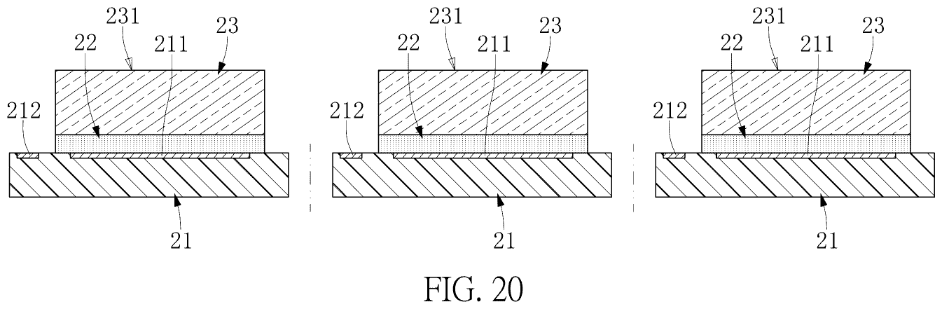

Referring to FIG. 18 to FIG. 20, a fourth embodiment of the present disclosure, which is similar to the third embodiment of the present disclosure, is provided. For the sake of brevity, descriptions of the same components or steps in the third and fourth embodiments of the present disclosure (e.g., the chip-bonding step and the packaging step) will be omitted herein, and the following description only discloses different features between the third and fourth embodiments.

In the modularizing step of the present embodiment, a first optical colloid 22a (e.g., a photosensitive colloid) is formed on the predetermined sensing regions 211a of the first wafer 21a in a spraying manner and is in a semi-solidified state (i.e., a B-stage mode), the first glasses 23 are adhered to the first optical colloid 22a and respectively correspond in position to the predetermined sensing regions 211a, and portions of the first optical colloid 22a not in contact with the first glasses 23 are removed so as to enable the first optical colloid 22a to respectively form the first transparent adhesive layers 22 spaced apart from each other.

### Beneficial Effects of the Embodiments

In conclusion, the sensor chip and the light-emitting chip in the sensor package structure of the present disclosure are provided with the first transparent adhesive layer and the second transparent adhesive layer that are respectively stacked thereon for adhering the first glass and the second glass, such that the opaque encapsulant can be configured to replace the conventional housing, thereby effectively reducing a manufacturing cost and an overall size of the sensor package structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure with no air cavity therein, comprising:
a substrate having an upper surface and a lower surface that is opposite to the upper surface;
a sensing module disposed on the substrate and including:
a sensor chip mounted on the upper surface of the substrate and electrically coupled to the substrate, wherein a top surface of the sensor chip has a sensing region;
a first transparent adhesive layer adhered to the top surface of the sensor chip and stacked on the sensing region; and
a first glass adhered to the first transparent adhesive layer and configured to filter light of a first spectral band;
a light-emitting module disposed on the substrate and spaced apart from the sensing module, wherein the light-emitting module includes:
a light-emitting chip mounted on the upper surface of the substrate and electrically coupled to the substrate;
a second transparent adhesive layer adhered to the light-emitting chip and stacked on a light-emitting surface of the light-emitting chip; and
a second glass adhered to the second transparent adhesive layer, wherein an outer surface of the second glass is coplanar with an outer surface of the first glass, and the second glass is configured to filter light of a second spectral band that is different from the first spectral band; and
an opaque encapsulant formed on the upper surface of the substrate, wherein the sensing module and the light-emitting module are embedded in the opaque encapsulant, and at least part of the outer surface of the first glass and at least part of the outer surface of the second glass are exposed from the opaque encapsulant.

2. The sensor package structure according to claim 1, wherein the substrate includes at least one first bonding pad and at least one second bonding pad that are arranged on the upper surface thereof, the sensor chip has at least one connection pad arranged on the top surface thereof, and the light-emitting chip has at least one second connection pad arranged adjacent to the light-emitting surface, wherein the sensing module includes at least one first metal wire that connects the at least one first bonding pad and the at least one first connection pad, and the at least one first metal wire is at least partially embedded in the opaque encapsulant, and wherein the light-emitting module includes at least one second metal wire that connects the at least one second bonding pad and the at least one second connection pad, and the at least one second metal wire is at least partially embedded in the opaque encapsulant.

3. The sensor package structure according to claim 2, wherein the at least one first metal wire is entirely embedded in the opaque encapsulant.

4. The sensor package structure according to claim 3, wherein the sensing region has a main segment and two sub-segments that extend from the main segment, and the at least one first connection pad is arranged in a region surrounded by the main segment and the two sub-segments, and wherein a projection region defined by orthogonally projecting the first glass onto the top surface of the sensor chip overlaps an entirety of the main segment and does not overlap the two sub-segments and the at least one first connection pad.

5. The sensor package structure according to claim 3, wherein the sensing region has a main segment and two sub-segments that extend from the main segment, and the at least one first connection pad is arranged in a region surrounded by the main segment and the two sub-segments, wherein the first glass has an inner surface that is opposite to the outer surface thereof and an avoidance slot that is recessed from the inner surface thereof, and a part of the at least one first metal wire is located in the avoidance slot, and wherein a projection region defined by orthogonally projecting the first glass onto the top surface of the sensor chip overlaps an entirety of the main segment, the two sub-segments, and the at least one first connection pad.

6. The sensor package structure according to claim 1, wherein an outer lateral edge of the first glass is flush with an outer lateral edge of the first transparent adhesive layer, and an outer lateral edge of the second glass is flush with an outer lateral edge of the second transparent adhesive layer.

7. The sensor package structure according to claim 1, wherein an interior of the sensor package structure has no air cavity.

8. A manufacturing method of a sensor package structure with no air cavity therein, the manufacturing method comprising:
a chip-bonding step implemented by mounting a sensor chip and a light-emitting chip onto an upper surface of a substrate, wherein the sensor chip and the light-emitting chip are spaced apart from each other;
an adhering step implemented by adhering a first glass onto a sensing region of the sensor chip through a first transparent adhesive layer so as to be jointly defined as a sensing module, and by adhering a second glass onto a light-emitting surface of the light-emitting chip through a second transparent adhesive layer so as to be jointly defined as a light-emitting module, wherein an outer surface of the second glass is coplanar with an outer surface of the first glass, the first glass is configured to filter light of a first spectral band, and the second glass is configured to filter light of a second spectral band that is different from the first spectral band; and
a packaging step implemented by forming an opaque encapsulant on the upper surface of the substrate, wherein the sensing module and the light-emitting module are embedded in the opaque encapsulant, and at least part of the outer surface of the first glass and at least part of the outer surface of the second glass are exposed from the opaque encapsulant.

9. The manufacturing method according to claim 8, wherein, in the adhering step, a first optical colloid and a second optical colloid are respectively formed on the sensing region of the sensor chip and the light-emitting surface of the light-emitting chip in a dispensing manner, the first glass and the second glass are respectively adhered to the first optical colloid and the second optical colloid, and the first optical colloid and the second optical colloid are solidified to respectively form the first transparent adhesive layer and the second transparent adhesive layer.

10. The manufacturing method according to claim 8, further comprising a preparing step before implementing the adhering step, wherein the preparing step is implemented by adhering a first optical colloid tape to a first glass layer and then cutting the first glass layer and the first optical colloid tape to form a plurality of the first glasses spaced apart from each other and the first transparent adhesive layers that are respectively adhered to the first glasses, and wherein, in the adhering step, one of the first glasses is adhered to the sensing region of the sensor chip through a corresponding one of the first transparent adhesive layers.

11. The manufacturing method according to claim 10, wherein, in the preparing step, a second optical colloid tape is adhered to a second glass layer, and the second glass layer and the second optical colloid tape are cut to form the second glasses spaced apart from each other and the second transparent adhesive layers that are respectively adhered to the second glasses, and wherein, in the adhering step, one of the second glasses is adhered to the light-emitting surface of the light-emitting chip through a corresponding one of the second transparent adhesive layers.

12. A manufacturing method of a sensor package structure with no air cavity therein, the manufacturing method comprising:
a modularizing step implemented by respectively adhering a plurality of first glasses onto predetermined sensing regions of a first wafer through a plurality of first transparent adhesive layers, and then cutting the first wafer to form a plurality of sensor chips that are spaced apart from each other and that have the predetermined sensing regions, respectively, wherein each of the sensor chips, a corresponding one of the first transparent adhesive layers, and a corresponding one of the first glasses are jointly defined as one of a plurality of sensing modules;
a chip-bonding step implemented by mounting the sensor chip of one of the sensing modules and a light-emitting module onto an upper surface of a substrate, wherein the light-emitting module includes a light-emitting chip mounted on the upper surface, a second transparent adhesive layer adhered to the light-emitting chip, and a second glass that is adhered to the second transparent adhesive layer, and wherein the first glass is configured to filter light of a first spectral band, and the second glass is configured to filter light of a second spectral band that is different from the first spectral band; and
a packaging step implemented by forming an opaque encapsulant on the upper surface of the substrate, wherein the sensing module and the light-emitting module are embedded in the opaque encapsulant, and at least part of an outer surface of the first glass and at least part of an outer surface of the second glass are exposed from the opaque encapsulant.

13. The manufacturing method according to claim 12, wherein, in the modularizing step, a plurality of first optical colloids are respectively formed on the predetermined sensing regions of the first wafer in a dispensing manner for being spaced apart from each other, the first glasses are respectively adhered to the first optical colloids, and the first optical colloids are solidified to respectively form the first transparent adhesive layers.

14. The manufacturing method according to claim 12, wherein in the modularizing step, a first optical colloid is formed on the predetermined sensing regions of the first wafer in a spraying manner, the first glasses are adhered to the first optical colloid and respectively correspond in position to the predetermined sensing regions, and portions of the first optical colloid not in contact with the first glasses are removed so as to enable the first optical colloid to respectively form the first transparent adhesive layers spaced apart from each other.

15. The manufacturing method according to claim 14, wherein the first optical colloid is a photosensitive colloid.

16. A sensor package structure with no air cavity therein, comprising:
a substrate having an upper surface and a lower surface that is opposite to the upper surface;
a sensing module disposed on the substrate and including:
a sensor chip mounted on the upper surface of the substrate and electrically coupled to the substrate, wherein a top surface of the sensor chip has a sensing region;
a first transparent adhesive layer adhered to the top surface of the sensor chip and stacked on the sensing region; and
a first glass adhered to the first transparent adhesive layer and configured to filter light of a first spectral band; and
an opaque encapsulant formed on the upper surface of the substrate, wherein the sensing module is embedded in the opaque encapsulant, and at least part of the outer surface of the first glass is exposed from the opaque encapsulant.

17. The sensor package structure according to claim 16, wherein the substrate includes at least one first bonding pad that is arranged on the upper surface thereof, and the sensor chip has at least one connection pad arranged on the top surface thereof, and wherein the sensing module includes at least one first metal wire that connects the at least one first bonding pad and the at least one first connection pad, and the at least one first metal wire is at least partially embedded in the opaque encapsulant.

18. The sensor package structure according to claim 17, wherein the at least one first metal wire is entirely embedded in the opaque encapsulant.

19. The sensor package structure according to claim 18, wherein the sensing region has a main segment and two sub-segments that extend from the main segment, and the at least one first connection pad is arranged in a region surrounded by the main segment and the two sub-segments, and wherein a projection region defined by orthogonally projecting the first glass onto the top surface of the sensor chip overlaps an entirety of the main segment and does not overlap the two sub-segments and the at least one first connection pad.

20. The sensor package structure according to claim 18, wherein the sensing region has a main segment and two sub-segments that extend from the main segment, and the at least one first connection pad is arranged in a region surrounded by the main segment and the two sub-segments, wherein the first glass has an inner surface that is opposite to the outer surface thereof and an avoidance slot that is recessed from the inner surface thereof, and a part of the at least one first metal wire is located in the avoidance slot, and wherein a projection region defined by orthogonally projecting the first glass onto the top surface of the sensor chip overlaps an entirety of the main segment, the two sub-segments, and the at least one first connection pad.
